(19) United States
(12) Patent Application Publication
(10) Pub. No.: US 2024/0414843 A1
(43) Pub. Date: Dec. 12, 2024

(54) CIRCUIT BOARD, ELECTRONIC DEVICE AND METHOD FOR FORMING THE SAME

(71) Applicant: GOERTEK INC., Weifang (CN)

(72) Inventor: Katsumi SAITO, Weifang (CN)

(21) Appl. No.: 18/811,878

(22) Filed: Aug. 22, 2024

Related U.S. Application Data
(63) Continuation of application No. PCT/CN2022/093222, filed on May 17, 2022.

(51) Int. Cl. H05K 1/11; H05K 1/02; H05K 1/18; H05K 3/34

(52) U.S. Cl. CPC H05K 1/11; H05K 1/0237; H05K 1/181; H05K 3/34; H05K 2201/10356

(57) ABSTRACT

Disclosed are a circuit board with a capability of suppressing conduction failure caused by undesirable flux, an electronic device including the circuit board, and a method for forming the circuit board are provided. The circuit board includes a base; a conductive circuit pattern formed on a surface of the base; and a concaved area formed in the base, wherein the concaved area recesses from the surface of the base and is joined to the conductive circuit pattern. With the proposed circuit board, the flux flow is managed and prevented from intruding into the conductive area of the circuit pattern.

### CROSS-REFERENCE TO RELATED APPLICATIONS

This application is a continuation application of International Application No. PCT/CN2022/093222, filed on May 17, 2022. The disclosure of the above-mentioned application is incorporated herein by reference in its entirety.

### TECHNICAL FIELD

The present disclosure generally relates to circuit board, and in particular, to a circuit board that is adapted to prevent an adverse effect caused on an electronic component due to flux and the like that are produced in soldering.

### BACKGROUND

Generally, in manufacturing a circuit board such as a printed circuit board (PCB), a flexible printed circuit board (FPC), a laser direct structure (LDS), and the like, after forming circuit patterns, usually including wiring patterns and land patterns on a base plate, various electronic components may be mounted to the circuit board by a soldering process in which solder paste containing flux is used for stable soldering. Flux aids in soldering and de-soldering processes by removing oxide films which form on the surface of metals being soldered.

Flux is inclined to melt and flow when the solder paste is heated. As shown in FIG. 1, for any soldering point on the circuit patterns, the melted flux may flow around the soldering point, and therefore may intrude into undesirable area on the circuit patterns.

Flux consists of water and active components and has a water absorption property and a moisture absorption property. In other words, basically flux is insulator. If flux flows and intrudes into undesirable area and adheres onto that area, the area will lose the conductivity. Hence, if flux flows and intrudes onto conductive areas of the circuit patterns, it is usually needed to remove the flux.

Conventionally, in case of design having soldering performed near the conductive area of the circuit patterns, flux cleaning process is added in manufacturing the circuit board. Alternatively, large-scale soldering equipment may be used in the soldering process to avoid the flux from adhering onto the conductive area. Inevitably, additional costs and tedious operations are involved.

In this concern, to prevent flux from adhering onto conductive surface in soldering process, there is need for improved circuit board structure that is adapted to prevent adverse effect caused due to the flux.

### SUMMARY

In view of the above, to provide the circuit board with a capability of suppressing conduction failure caused by undesirable flux, the present disclosure proposes a novel structure of circuit board. At least following technical solutions are provided to achieve the above objective.

In one aspect, a circuit board is provided. The circuit board includes a base; a conductive circuit pattern formed on a surface of the base; and a concaved area formed in the base, wherein the concaved area recesses from the surface of the base and is joined to the conductive circuit pattern.

In one embodiment, the concaved area is surrounded by the conductive circuit pattern. In this case, the concaved area is closed ended within the area of the conductive circuit pattern.

In one embodiment, the conductive circuit pattern includes a soldering area for soldering a first electronic component to the circuit board, and the concaved area is provided near the soldering area.

In one embodiment, the conductive circuit pattern further includes a conductive contact area for electrically connecting with a second electronic component, wherein the conductive contact area is arranged adjacent to the soldering area and is electrically connected with the soldering area, and the concaved area is provided between the contact area and the soldering area.

In one embodiment, a distance between the conductive contact area and the soldering area is in a range of 0.5 mm-50 mm, and preferably less than 20 mm.

In one embodiment, the concaved area includes one or more slits each joined to the conductive circuit pattern.

In one embodiment, the one or more slits are straight or curved.

In one embodiment, each of the one or more slits has a width of 0.1 mm-5 mm.

In one embodiment, each of the one or more slits forms a structure capable of capillary action for leading a flow of flux at time of soldering.

In one embodiment, the conductive circuit pattern is a ground GND line, and the first electronic component is a radio frequency RF cable.

In one embodiment, the conductive contact area provides electrical conduction to GND part of the second electronic component by screwing, contact or soldering.

In one embodiment, the concaved area is arranged to permit flux produced at time of soldering to escape from the conductive circuit pattern.

In a second aspect, an electronic device is provided. The electronic device includes any one of the foregoing circuit boards.

In one embodiment, the electronic device further includes a first electronic component soldered to the circuit board at a soldering area of the conductive circuit pattern, and a second electronic component electrically connected to the circuit board at a contact area of the conductive circuit pattern. The concaved area is provided between the soldering area and the contact area.

In one embodiment, the first electronic component is a RF cable, the conductive circuit pattern is a ground line, and a grounding part of the electronic device contacts with the ground line in the contact area.

In a third aspect, a method for manufacturing a circuit board is provided. The method includes forming a conductive circuit pattern on a surface of a base; forming a concaved area in the base, wherein the concaved area recesses from the surface of the base; and joining the concaved area to the conductive circuit pattern.

In one embodiment, the method further includes soldering a first electronic component to the circuit board in a soldering area in the conductive circuit pattern; and contacting a second electronic component to the circuit board in a contact area in the conductive circuit pattern. Flux melt in process of soldering the first electronic component and flowing out of the soldering area is guided by the concaved area away from entering the contact area.

In one embodiment, the first electronic component is a RF cable.

In a fourth aspect, a circuit board is provided. The circuit board includes a base; a conductive circuit pattern formed on a surface of the base; and a concaved area formed on the surface of the base, wherein the concaved area recesses from a surface of the conductive circuit pattern to the surface of the base, and the concaved area includes multiple portions in an interleaved arrangement with portions of the conductive circuit pattern, or the concaved area is surrounded by the conductive circuit pattern.

In the present disclosure, a circuit board adapted to prevent conduction failure due to the flux is proposed. With the proposed circuit board, the flux flow is managed and prevented from intruding into the conductive area of the circuit pattern. In the circuit board provided according to embodiments of the present disclosure, concaved area is formed on the base of the circuit board. The concaved area recesses from the surface of the base in the circuit board, and is joined to the conductive circuit pattern on the base of the circuit board. Hence, the concaved area has an altitude lower than the conductive area of the circuit pattern, and forms a recess to guide and accommodate the melted flux, thereby preventing the flux from flowing and adhering to the conductive area of the circuit pattern and thus preventing the so-caused conductive failure.

As compared with the conventional technology for removing the extra flux by additional flux cleaning process or using expensive soldering equipment to prevent extra flux, the circuit board as proposed according to the embodiments of the present disclosure may manage the flux flow in the soldering process, the additional flux cleaning process may be eliminated, and therefore the cost is saved and the soldering process for such circuit board is simplified.

In the present disclosure, the concaved area may include one or more narrow slits. Due to the narrow width of the slit(s), capillary action occurs in case of the flux flow, and therefore the flux flow can be guided into the concaved area efficiently and effectively.

In the present disclosure, these slits placed ensure adequate soldering area and ensure adequate conductive line between the soldering area and the conductive area since there is no need to space the soldering area and the conductive area with large distance.

### BRIEF DESCRIPTION OF THE DRAWINGS

For clearer illustration of the technical solutions according to embodiments of the present disclosure or conventional techniques, hereinafter briefly described are the drawings to be applied in embodiments of the present disclosure or conventional techniques. Apparently, the drawings in the following descriptions are only some embodiments of the present disclosure, and other drawings may be obtained by those skilled in the art based on the provided drawings without creative efforts.

FIG. 1 is a schematic diagram of a circuit board including soldering point at which flux melts and flows.

FIG. 2 is a schematic diagram of a circuit board to which a radio frequency cable is soldered according to an embodiment of the present disclosure.

FIG. 3 is a schematic top view of a circuit board provided according to an embodiment of the present disclosure.

FIG. 4A is a schematic top view of a circuit board provided according to another embodiment of the present disclosure.

FIG. 4B is a schematic top view of a circuit board provided according to yet another embodiment of the present disclosure.

FIG. 4C is a schematic diagram of a circuit board provided according to yet another embodiment of the present disclosure.

FIG. 4D is a schematic diagram of a circuit board provided according to yet another embodiment of the present disclosure.

FIG. 5 is a schematic top view of a circuit board provided according to an embodiment of the present disclosure.

FIG. 6 is a schematic top view showing flows of flux in the circuit board of FIG. 5.

FIG. 7 is a schematic top view of a circuit board including RF cable connection provided according to an embodiment of the present disclosure.

FIG. 8 is a schematic block diagram of an electronic device provided according to an embodiment of the present disclosure.

FIG. 9 is a schematic flowchart of a method for forming a circuit board according to an embodiment of the present disclosure.

FIG. 10 is a schematic cross section of a circuit board provided according to another embodiment of the present disclosure.

### DETAILED DESCRIPTION OF THE EMBODIMENTS

Hereinafter technical solutions in embodiments of the present disclosure are described in conjunction with the drawings in embodiments of the present closure. Apparently, the described embodiments are only some rather than all of the embodiments of the present disclosure. Any other embodiments obtained based on the embodiments of the present disclosure by those skilled in the art without any creative effort fall within the scope of protection of the present disclosure.

It should be noted that, terms such as “first”, “second”, “third”, “fourth” and the like are only used herein to distinguish one entity or operation from another, rather than to necessitate or imply that an actual relationship or order exists between the entities or operations. Furthermore, the terms such as “include”, “comprise” or any other variants thereof means to be non-exclusive. Therefore, a process, a method, an article or a device including a series of elements include not only the disclosed elements but also other elements that are not clearly enumerated, or further include inherent elements of the process, the method, the article or the device. Unless expressively limited, the statement “including a . . . ” does not exclude the case that other similar elements may exist in the process, the method, the article or the device other than enumerated elements.

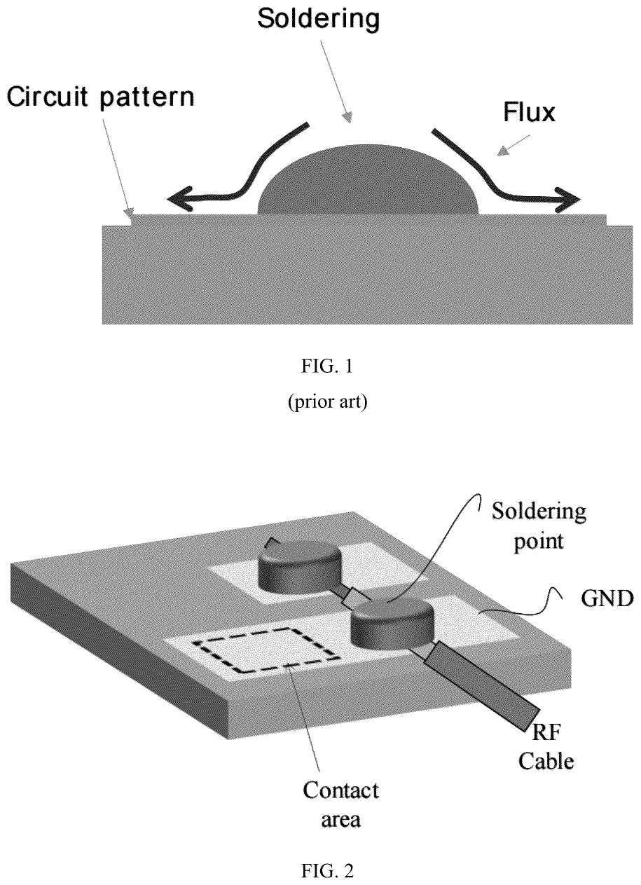

In a circuit board such as a printed circuit board (PCB), a flexible printed circuit board (FPC), a laser direct structure (LDS), and the like, soldering is in general used for conductive connecting and fixing between a circuit pattern on the circuit board and an electrical component such as a cable. And it is often the case that we have to do the soldering near the conductive area on the same circuit pattern. Flux, which is commonly used in the soldering process, is inclined to melt and flow when the solder paste is heated. As shown in FIG. 1, for any soldering point on the circuit patterns, the melted flux may flow around the soldering point, and therefore may intrude into undesirable area on the circuit patterns.

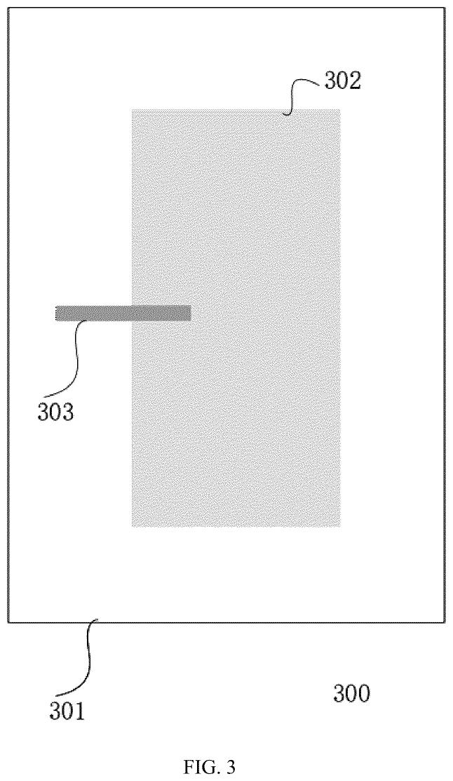

In particular, as an example as shown in FIG. 2, in case of radio frequency (RF) cable connection in an electrical device, the RF cable is usually soldered to the circuit patterns on the circuit board, and especially, the RF cable is soldered to the ground wiring pattern (GND). Furthermore, it is needed to conduct main ground part of the electrical device to the GND wiring pattern by, for example, screwing or contact pin to a contact area of the GND wiring pattern near the GND soldering point of the RF cable for good RF performance. Generally, the closer between the contact area and the soldering point, the better the RF performance.

When soldering the RF cable to the circuit pattern, flux may melt and flow around soldering area. And the amount of the flux and the direction of flow aren't stable. If the insulating flux adheres on conductive area of the circuit pattern, conduction failure may be caused.

Conventionally, the undesirable flux needs to be removed by additional cleaning procedures in the soldering process, or the large-scale soldering equipment capable of avoiding the flux from adhering onto the conductive area is used. Inevitably, additional costs and tedious operations are involved.

In the present disclosure, a circuit board adapted to prevent conduction failure due to the flux is proposed. With the proposed circuit board, the flux flow is managed and prevented from intruding into the conductive area of the circuit pattern. In the circuit board provided according to embodiments of the present disclosure, concaved area is formed on the base of the circuit board. The concaved area recesses from the surface of the base in the circuit board, and is joined to the conductive circuit pattern on the base of the circuit board. Hence, the concaved area has an altitude lower than the conductive area of the circuit pattern, and forms a recess to guide and accommodate the melted flux, thereby preventing the flux from flowing and adhering to the conductive area of the circuit pattern and thus preventing the so-caused conductive failure.

In some embodiments, the concaved area may include one or more slits, which are in shape of lines, provided adjacent to each other on the circuit pattern. And these slits are placed leading flux flow for not flowing into the conductive area. The slits may be straight or curved, or in other shapes.

In some embodiments, the slit is narrow in width. Due to the narrow width of the slit(s), capillary action occurs in case of the flux flow, and therefore the flux flow can be guided into the concaved area efficiently and effectively.

In some embodiments, these slits placed ensure adequate soldering area and ensure adequate conductive line between the soldering area and the conductive area.

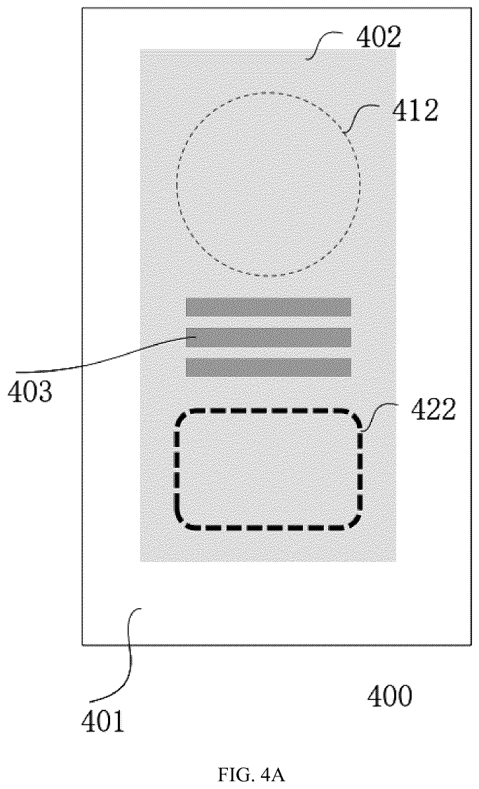

FIG. 3 is a schematic top view of a circuit board 300 provided according to an embodiment of the present disclosure. The circuit board 300 includes a base 301 and a circuit pattern 302 formed on the base 301. The base 301 is a board made of different materials. Materials for the base 301 of the circuit board 300 can be resin based, fiberglass based, epoxy glass, metal board, flame retardant, or any suitable material, which is not limited in this disclosure. Circuit patterns, usually including wiring patterns, land patterns and the like, may be formed by printing, etching or other schemes on the base 301. The circuit patterns may be formed with various materials such as coppers or the like. Electronic components may then be soldered onto this circuit board 300 to form an electronic assembly.

It should be noted that the circuit board 300 may be formed with other materials and other technologies, and the present disclosure is not limited in this aspect. For example, the circuit board 300 may be a printed circuit board (PCB), a flexible printed circuit board (FPC), a laser direct structure (LDS), and the like.

Among them, the conductive circuit pattern 302 is formed on the surface of the base 301. In an exemplary embodiment, the conductive circuit pattern 302 may be a wiring pattern or may be a trace, onto which electronic components may be soldered, contact, screwed, or otherwise electrically connected. Although the circuit pattern 302 is shown in FIG. 3 as a rectangle, one of ordinary skills in the art may understand that the circuit pattern 302 may be in any shape and any size as desirable.

The circuit board 300 further includes a concaved area 303. The concaved area 303 is formed in the base 301, and is recessed from the surface of the base 301. The concaved area 303 is joined to the conductive circuit pattern 302. In other words, the concaved area 303 is in physical connection with the circuit pattern 302. Since the circuit pattern 302 is formed on the surface of the base 301 while the concaved area 303 is recessed from the surface of the base 301, the level of the concaved area 303 is lower than the portion of the circuit pattern 302. In addition, the concaved area 303 is joined to the conductive circuit pattern 302, therefore if there is any flow of flux in the portion of the conductive circuit pattern 302, the flow will be led to the concaved area 303 and be hold in the concaved area 303. By virtue of the concaved area 303, the flux will not enter other conductive area of the circuit pattern 302 or other conductive area on the circuit board 300; and therefore, undesirable conduction failure in the circuit board 300 is avoided.

The concaved area 303 may be in a variety of shapes and dimensions. In an exemplary embodiment, the concaved area 303 may be in the form of a slit formed in the base 301, as shown in FIG. 3. In practice, the slit may be narrow in width and deep in depth, for example, the width of the slit is approximately 0.1 mm-5 mm and the depth of the slit is approximately 30 μm or more.

Alternatively, in another embodiment, the concaved area 303 may include a slit and a pit connected with each other (not shown), with the slit being joined with the conductive circuit pattern 302 and the pit being arranged farther from the circuit pattern. As will be understood, forming one or more narrow slits for the concaved area is beneficial in leading the flow of flux due to the capillary action; hence the melted flux can be effectively guided away from the conductive circuit pattern in soldering process. And providing the pit connected with the circuit pattern through the slit(s), a space for accommodating the flux is formed.

It is noted herein that although given number of slits are shown in the drawings to illustrating the solution according to embodiments of the present disclosure, the number of the slits may depend on application needs and the present disclosure is not limited in this aspect.

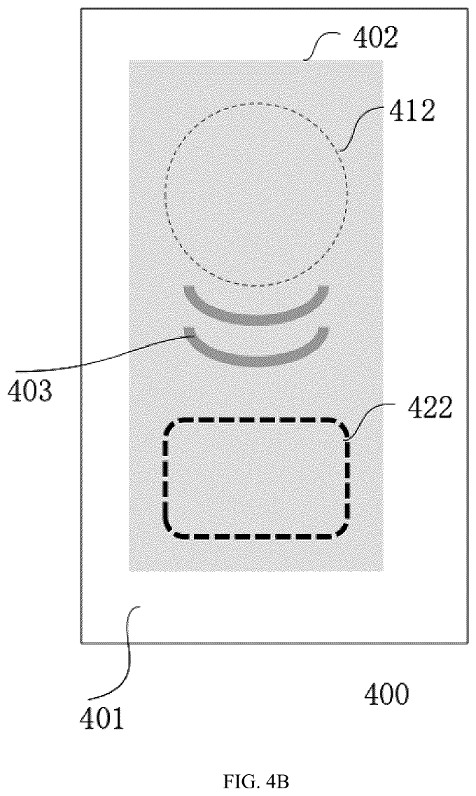

It is noted herein that the concaved area may be in various structures, sizes and arrangements, and the present disclosure is not limited in this aspect. For example, the concaved area may include multiple straight or curved slits, as shown in FIGS. 4a and 4b. Alternatively, the concaved area may be in a combined structure of slits and recesses, as shown in FIGS. 4c and 4d.

In exemplary embodiments, the concaved area is surrounded by the conductive circuit pattern, i.e., the concaved area is formed within the range of the conductive circuit pattern, as shown in FIGS. 4a and 4b. In such cases, the footprint of the conductive circuit pattern covers that of the concaved area, and no additional space on the circuit board is occupied by the concaved area. In these embodiments, the concaved area includes closed end slits.

Although not shown, it is noted that the circuit board 300 may be single-sided or double-sided. It is also noted that circuit board 300 may be in a multi-layer structure, for example, a laminated sandwich structure of conductive and insulating layers. Additionally, vias, plated-through holes that allow interconnections between layers and the like may be formed in the circuit board 300. In practice, the circuit board 300 may include a variety of patterns, elements, components and the like.

The circuit pattern on the circuit board may be formed in any possible schemes known in the art or proposed in the future. For example, the circuit pattern may be formed by silk screen printing, photoengraving, direct imaging techniques, maskless lithography or direct imaging, PCB milling, laser resist ablation, laser etching, chemical etching, or the like. The present disclosure is not limited in this aspect.

Detailed description of the present disclosure is made below by referring to FIG. 4A. As shown, for the circuit board 400, the conductive circuit pattern 402 formed on the base 401 includes a soldering area 412 and a contact area 422. The soldering area 412 is for soldering an electronic component, such as a chip, a RF cable, and the like, to the circuit board 400. The contact area 422 is arranged adjacent to the soldering area 412. The contact area 422 is electrically connected with the soldering area 412 since both the contact area 422 and the soldering area 412 are formed on the same circuit pattern 402. The contact area 422 is configured for connecting with another electronic component, by various ways such as screwing, contact pin, or the like.

In an exemplary embodiment, the contact area 422 and the soldering area 412 are close to each other. For example, a distance between the contact area 422 and the soldering area 412 is in a range of 0.5 mm-50 mm, and preferably less than 20 mm. Given the small distance between the contact area 422 and the soldering area 412, flux melt in the soldering area 412 in soldering process is inclined to flow into the contact area, which may result in conduct failure in the contact area.

To avoid the undesirable conduct failure, a concaved area 403, which may be in forms such as slits, pits, and the like, is arranged between the contact area 422 and the soldering area 412. By virtue of the function of guiding and/or accommodating flux of the concaved area 403, the flux from the soldering area 412 can be guided away from the contact area 422, and therefore the conduct failure in the contact area 422 may be avoided.

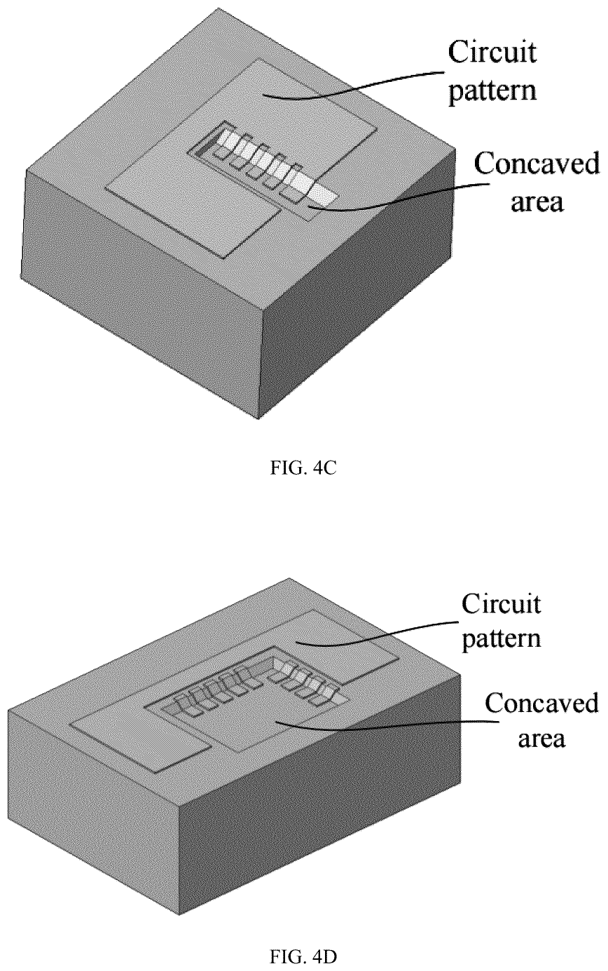

The concaved area may be in other arrangements. Reference is made to FIG. 5, in which the circuit pattern is in the same configuration as that in FIG. 4A. As shown, the circuit board 500 includes a base 501 and a circuit pattern 502. The circuit pattern 502 includes a soldering area 512 and a contact area 522. The soldering area 512 is for soldering a first electronic component (not shown) to the circuit board 500, and the contact area 522 is for electrically connecting with a second electronic component (not shown). The soldering area 512 and the contact area 522 are close to each other.

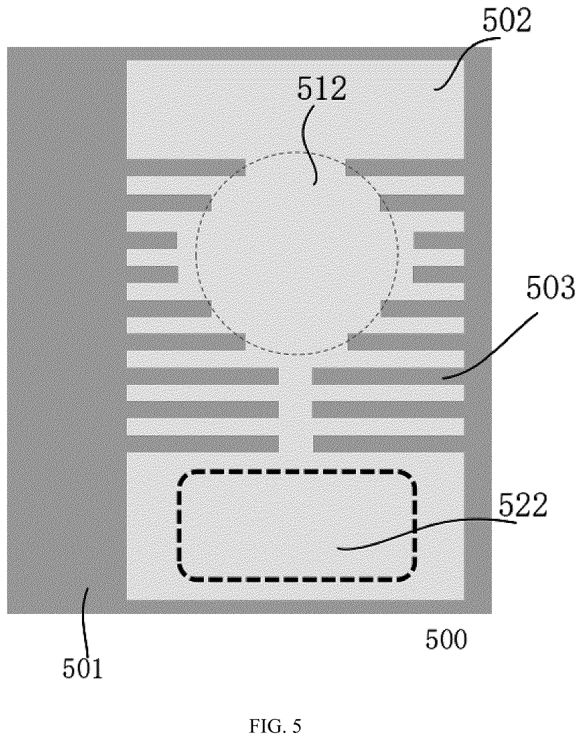

In this embodiment, the concaved area 503 includes multiple slits. Some of the slits are arranged around the soldering area 512, and some of the slits are arranged between the soldering area 512 and the contact area 522. Each of the slits is joined to the circuit pattern 502, and extends from the circuit pattern 502 to other portions on the base 501. Each of the slits may be narrow in width and may function like capillary. Hence, due to capillary action, any flux flowing out of the soldering area 512 will flow along the slits and therefore is prevented from entering the contact area 522 of the circuit pattern 502. The flow of the flux is schematically shown as the arrows in FIG. 6. As seen, the flows of flux will be guided in the slits and will not enter the contact area.

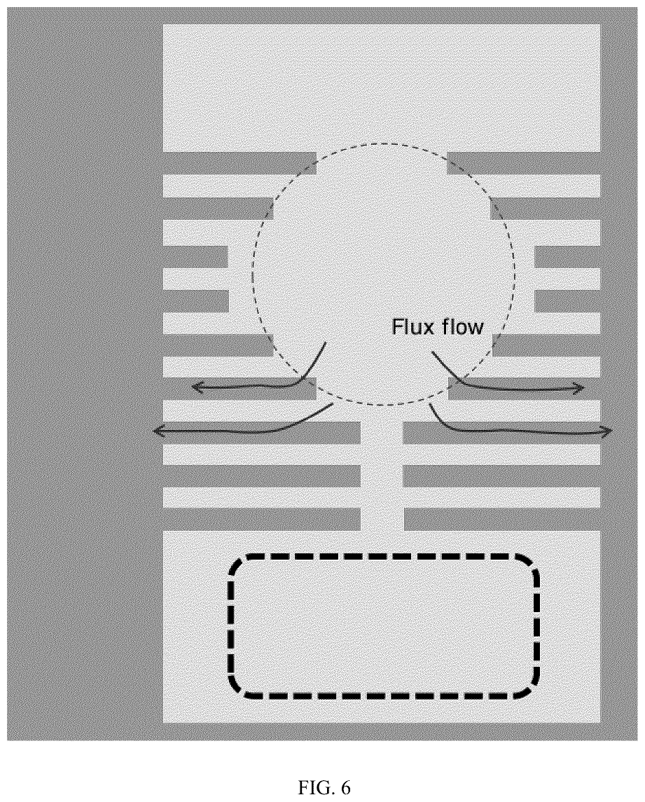

The circuit board as provided according to embodiment of the present disclosure is especially beneficial for the case of radio frequency (RF) cable connection. Detailed description is made below by referring to FIG. 7.

As shown in FIG. 7, on a base 701 of the circuit board 700, a signal line 712 and a ground (GND) line 722 are formed as separated circuit patterns. A RF cable 704 is connected to the signal line 712 and the GND line 722. The RF cable 704 is connected to the GND line 722 at the soldering area 732 by soldering. In addition, an electronic component, such as GND part of an electronic device including the RF cable, is electrically connected to a contact area 742 on the GND line 722. For good RF performance, it is needed to arrange the GND part of an electronic device as close to the soldering point of the RF cable on the GND line as possible. In other words, the contact area 742 is extremely close to the soldering area 732.

When soldering the RF cable 704 to the GND line 722, flux may melt and flow around soldering area 732. Since the amount of the flux and the direction of flux flow aren't stable, and given the short distance between the soldering area 732 and the contact area 742, the insulating flux is prone to enter the contact area 742 and may adhere on contact area 742. In this case, the contact area 742 may lose conductivity and the GND connection of the electronic device and other electronic components connected to the GND line may fail.

To address this issue, the circuit board 700 is provided with a concaved area 703. The concaved area 703 may be in any of the foregoing arrangements or in any combination thereof. The concaved area 703 is joined with the GND line 722, and therefore may function to guide the flux flowing out of the soldering area 732 away from the contact area 742 or other portions of the GND line 722. Thereby, the conduct failure of GND connection of the electronic device and other electronic component is avoided.

It is noted that the concaved area 703 as shown in FIG. 7 is exemplary, and the concaved area 703 may be in any of the foregoing described structures, shapes and dimensions. For example, the concaved area 703 may be closed ended within the GND line, or may extend out from the GND line to other portions of the base 701. The concaved area 703 may be multiple slits, a combination of slit(s) and pit(s), square shaped recesses, recesses of other shapes, or any combination thereof. The concaved area 703 may be arranged between the soldering area 732 and the contact area 742, or may be arranged around the soldering area 732, or may be arranged at other locations.

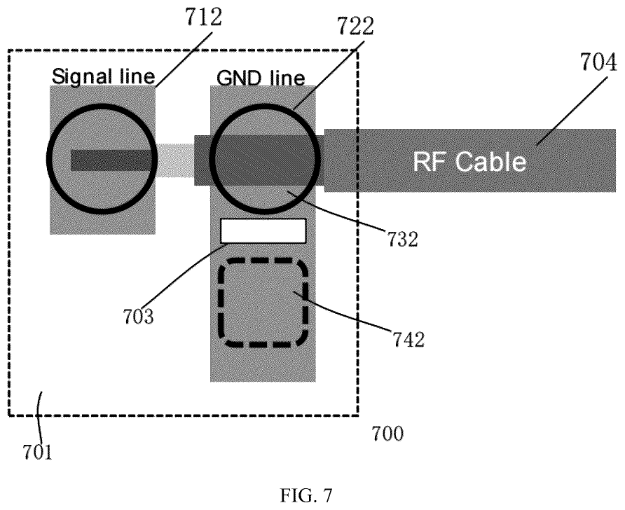

The circuit board as described above may be applied in a variety of electronic devices. Referring to FIG. 8, an electronic device, in which a circuit board according to embodiments of the present disclosure may be applied, is provided according to an embodiment of the present disclosure. Electronic device 800 of FIG. 8 may be a portable computer such as a laptop computer, a portable tablet computer, a mobile telephone, a mobile telephone with media player capabilities, a handheld computer, a remote control, a game player, a global positioning system (GPS) device, a desktop computer, a music player, a multi-touch electronic device, Augmented Reality (AR) glasses, Head Mounted Display (HMD), a combination of such devices, or any other suitable electronic device. As shown in FIG. 8, electronic device 800 may include an in-out circuitry 1100, a processor 1200 and storage 1300.

The processor 1200 may be a microprocessor and other suitable integrated circuit. The processor 1200 and storage 1300 may be configured for control the operation of the electronic device 800. In an exemplary implementation, the processor 1200 may run software stored in the storage 1300 for the electronic device 800, such as operating system functions, phone call applications, Internet browsing, email applications, media playback applications, control functions for controlling radio-frequency power amplifiers and other radio-frequency transceiver, etc.

The storage 1300 may include one or more different types of storage such as hard disk drive storage, nonvolatile memory (e.g., flash memory or other electrically-programmable-read-only memory), volatile memory (e.g., static or dynamic random-access-memory).

Communications protocols that may be implemented by the processor 1200 include Internet protocols, cellular telephone protocols, wireless local area network protocols (e.g., IEEE 802.11 protocols, referred to as WiFi®), protocols for other short-range wireless communications links such as the Bluetooth® protocol, etc.

The in-out circuitry 1100 is configured to implement input and output function of the electronic device 800. The in-out circuitry 1100 may include an input-output device 1111 and a wireless communication circuitry 1120. The input-output device 1111 may be a touch screen and other user input device such as buttons, joysticks, click wheels, scrolling wheels, touch pads, key pads, keyboards, microphones, cameras, etc. Furthermore, the input-output device 1111 may include display and audio devices such as liquid-crystal display (LCD) screens, light-emitting diodes (LEDs), organic light-emitting diodes (OLEDs), and other components that present visual information and status data.

The wireless communications circuitry 1120 may include radio-frequency (RF) transceiver circuitry 1121 formed from one or more integrated circuits, power amplifier circuitry, low-noise input amplifiers, passive RF components, and other circuitry for handling RF wireless signals. For example, the RF transceiver circuitry 1121 may include a cellular transceiver circuitry 1122 for handling wireless communications in cellular bands such as the bands at 600 MHz, 850 MHz, 900 MHZ, 1800 MHZ, and 1900 MHZ, and the 2100 MHz data band. The RF transceiver circuitry 1121 may also include a WIFI and Bluetooth transceiver circuitry 1123 that handles 2.4 GHz and 5 GHz bands for WiFi (IEEE 802.11) communications and the 2.4 GHz Bluetooth communications band. The Wireless communications circuitry 1120 can include circuitry for other short-range and long-range wireless links if desired. For example, wireless communications circuitry 1120 may include global positioning system (GPS) receiver equipment, wireless circuitry for receiving radio and television signals, paging circuits, etc.

The RF transceiver circuitry 1121 may be implemented using one or more integrated circuits and associated components (e.g., switching circuits, matching network components such as discrete inductors, capacitors, and resistors, and integrated circuit filter networks, etc.). These devices may be mounted on any suitable mounting structures. With one suitable arrangement, transceiver integrated circuits may be mounted on a printed circuit board.

The RF transceiver circuitry 1121 may include a circuit board as in the configuration as proposed in the embodiments of the present disclosure, such as the circuit board as described above by referring to FIG. 3, 4a-4d, 5-7 or variations thereof.

Connections within the RF circuitry 1121 may include any suitable conductive pathways over which radio-frequency signals may be conveyed including transmission line path structures such as coaxial cables, microstrip transmission lines, stripline transmission lines, etc.

The wireless communications circuitry 1120 may include antenna assembly 1124, which may be single band antenna that each cover a particular desired communications band or may be multi-band antenna. A multiband antenna may be used, for example, to cover multiple cellular telephone communications bands.

In addition to the shown components, the electronic device 800 may include other components for different functionalities. For example, the electronic device 800 generally includes a housing, which may be formed to serve as ground plane.

Other details of the electronic device 800 may refer to the forgoing description concerning the circuit board according to the embodiments of the present disclosure, and are not repeated herein.

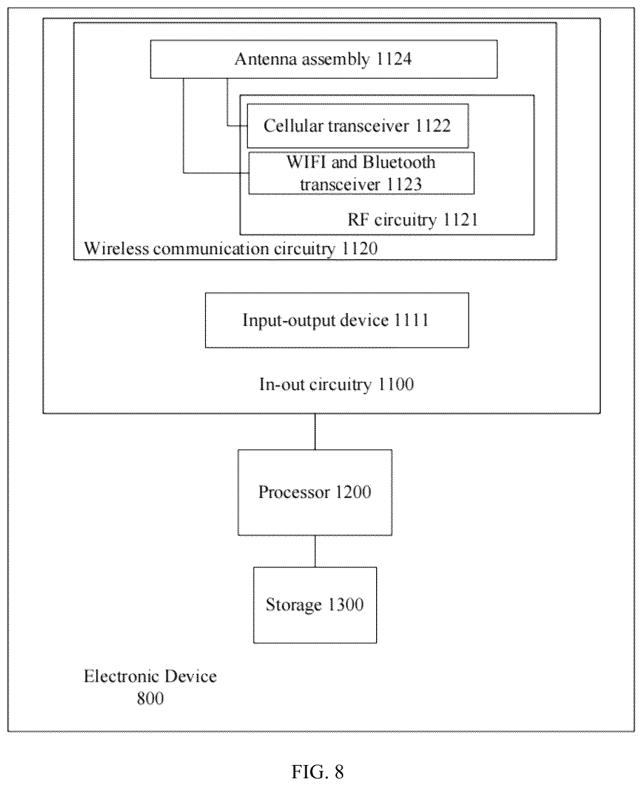

According to another embodiment of the present disclosure, it is provided a method for forming a circuit board as shown in FIGS. 3, 4a-4d, and 5-7. A flow chart of the method 900 for forming the circuit board according to the embodiments of the present disclosure is shown in FIG. 9. In exemplary embodiments, the method 900 may include steps 901-903.

In step 901, a conductive circuit pattern is formed on a surface of a base.

In step 902, a concaved area is formed in the base. The concaved area is recessed from the surface of the base. Hence, the level of the concaved area is lower than the conductive circuit pattern.

In step 903, the concaved area is joined to the conductive circuit pattern.

In some embodiments according to the present disclosure, the method further includes steps 904 and 905.

In step 904, a first electronic component is soldered to the circuit board in a soldering area in the conductive circuit pattern.

In step 905, a second electronic component is contacted to the circuit board in a contact area in the conductive circuit pattern.

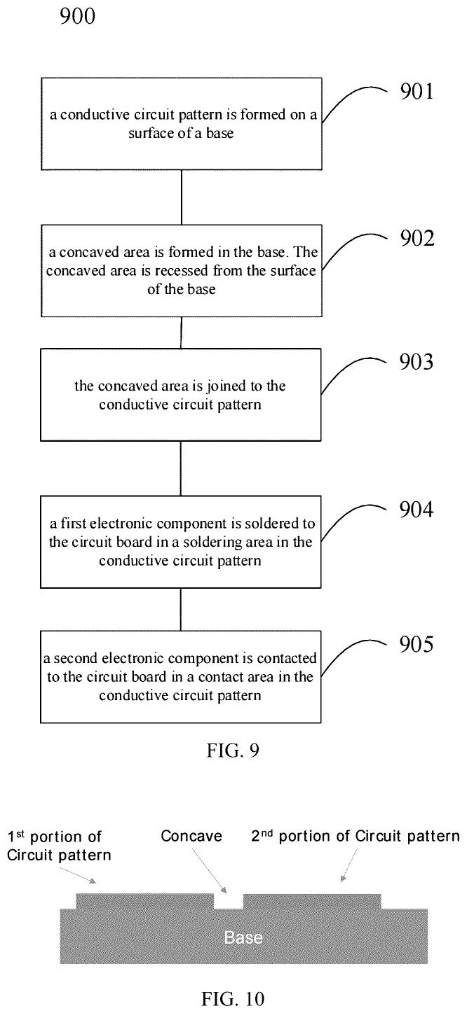

FIG. 10 shows a schematic cross section of a circuit board provided according to another embodiment of the present disclosure. The circuit board includes a base; a conductive circuit pattern formed on a surface of the base; and a concaved area formed on the surface of the base. In the drawing, the conductive circuit pattern is shown as including a first portion and a second portion, and those skilled in the art may understand that to ensure the conductivity of the circuit pattern the first portion and the second portion are electrically connected with each other. As shown, the concaved area recesses from a surface of the conductive circuit pattern to the surface of the base.

In one embodiment, the concaved area includes multiple portions in an interleaved arrangement with portions of the conductive circuit pattern. In such a case, the arrangement of the concaved area and the conductive circuit pattern may be in a top view similar to that shown in FIG. 5. In one exemplary embodiment, the concaved area is in form of fine-tooth comb, with portions interleaving or meshing with the teeth-formed portions of the conductive circuit pattern.

In one embodiment, the concaved area is surrounded by the conductive circuit pattern. In such as case, the arrangement of the concaved area and the conductive circuit pattern may be in a top view similar to that shown in FIG. 4a or 4b.

Due to the presence of the concaved area on the circuit board, when soldering electronic components to the circuit board, any extra flux will be guided by the concaved area and therefore will not enter other area of the circuit board.

The solution according to the present disclosure ensures conductive quality by preventing flux adhere on conductive surface. Furthermore, the solution according to the present disclosure affords cost saving because no additional process for flux cleaning is needed, and there is no need to use big equipment for soldering.

The embodiments of the present disclosure are described in a progressive manner, and each embodiment places emphasis on the difference from other embodiments. Therefore, one embodiment can refer to other embodiments for the same or similar parts. Since the methods disclosed in the embodiments correspond to the apparatuses disclosed in the embodiments, the description of the methods is simple, and reference may be made to the relevant part of the apparatuses.

According to the description of the disclosed embodiments, those skilled in the art can implement or use the present disclosure. Various modifications made to these embodiments may be obvious to those skilled in the art, and the general principle defined herein may be implemented in other embodiments without departing from the spirit or scope of the present disclosure. Therefore, the present disclosure is not limited to the embodiments described herein but confirms to a widest scope in accordance with principles and novel features disclosed in the present disclosure.

What is claimed is:

1. A circuit board, comprising:
a base;
a conductive circuit pattern formed on a surface of the base; and
a concaved area formed in the base, wherein the concaved area recesses from the surface of the base and is joined to the conductive circuit pattern.

2. The circuit board according to claim 1, wherein the concaved area is surrounded by the conductive circuit pattern.

3. The circuit board according to claim 1, wherein the conductive circuit pattern comprises a soldering area for soldering a first electronic component to the circuit board, and the concaved area is provided near the soldering area.

4. The circuit board according to claim 3, wherein the conductive circuit pattern further comprises a conductive contact area for electrically connecting with a second electronic component, wherein the conductive contact area is arranged adjacent to the soldering area and is electrically connected with the soldering area, and the concaved area is provided between the contact area and the soldering area.

5. The circuit board according to claim 4, wherein a distance between the conductive contact area and the soldering area is less than 20 mm.

6. The circuit board according to claim 1, wherein the concaved area comprises one or more slits each joined to the conductive circuit pattern.

7. The circuit board according to claim 6, wherein the one or more slits are straight or curved.

8. The circuit board according to claim 6, wherein each of the one or more slits has a width of 0.1 mm-5 mm.

9. The circuit board according to claim 6, wherein each of the one or more slits forms a structure capable of capillary action for leading a flow of flux at time of soldering.

10. The circuit board according to claim 4, wherein the conductive circuit pattern is a ground GND line, and the first electronic component is a radio frequency RF cable.

11. The circuit board according to claim 10, wherein the conductive contact area provides electrical conduction to GND part of the second electronic component by screwing, contact or soldering.

12. The circuit board according to claim 1, wherein the concaved area is arranged to permit flux produced at time of soldering to escape from the conductive circuit pattern.

13. A circuit board comprising:
a base;
a conductive circuit pattern formed on a surface of the base; and
a concaved area formed on the surface of the base, wherein the concaved area recesses from a surface of the conductive circuit pattern to the surface of the base, and the concaved area comprises a plurality of portions in an interleaved arrangement with portions of the conductive circuit pattern, or the concaved area is surrounded by the conductive circuit pattern.

14. An electronic device comprising a circuit board according to claim 1.

15. The electronic device according to claim 14, further comprising:
a first electronic component soldered to the circuit board at a soldering area of the conductive circuit pattern, and
a second electronic component electrically connected to the circuit board at a contact area of the conductive circuit pattern,
wherein the concaved area is provided between the soldering area and the contact area.

16. The electronic device according to claim 15, wherein the first electronic component is a RF cable, the conductive circuit pattern is a ground line, and a grounding part of the electronic device contacts with the ground line in the contact area.

17. A method for manufacturing a circuit board, comprising:
forming a conductive circuit pattern on a surface of a base;
forming a concaved area in the base, wherein the concaved area recesses from the surface of the base; and
joining the concaved area to the conductive circuit pattern.

18. The method according to claim 17, further comprising:
soldering a first electronic component to the circuit board in a soldering area in the conductive circuit pattern; and
contacting a second electronic component to the circuit board in a contact area in the conductive circuit pattern;
wherein flux melt in process of soldering the first electronic component and flowing out of the soldering area is guided by the concaved area away from entering the contact area.

19. The method according to claim 18, wherein the first electronic component is a RF cable.
